(19) United States
(12) Patent Application Publication
(10) Pub. No.: US 2005/0243535 A1
(43) Pub. Date: Nov. 3, 2005

(54) Circuit blank for an equipment shelf

(76) Inventor: Bradley D. Shaw, Plaistow, NH (US)

Correspondence Address: Lucent Technologies Inc.;Docket Administrator - Room - 3J- 219, 101 Crawfords Corner Road, Holmdel, NJ, 07733-3030, US

(21) Appl. No.: 10/836,413

(22) Filed: Apr. 30, 2004

(51) Int. Cl. H05K 7/14; H05K 7/18

(52) U.S. Cl. 361/801

(57) ABSTRACT

A circuit pack blank is provided for use in an equipment shelf that utilizes backplane connectors having shorting contacts. The circuit pack blank includes an integrally molded base and non-metallic connector tab adapted for insertion into a backplane connector such that the connector tab serves as an insulating layer thereby preventing electrical connection between the shorting contacts.

### TECHNICAL FIELD

This invention relates generally to communications systems and, more specifically, to circuit packs and backplanes used in such systems.

### BACKGROUND OF THE INVENTION

Complex electronic apparatus may require the interconnection of thousands of individual electronic devices. To manage the large number of required interconnections in a communication system, for example, such apparatus is often configured by affixing devices to circuit boards (also referred interchangeably hereinafter as circuit packs or circuit cards), and by interconnecting these circuit boards using a printed wire backplane. Collections of interconnected circuit boards and backplanes are often contained in housings referred to as equipment shelves. The backplane of an equipment shelf includes connectors for electrically mating with the circuit boards to facilitate the transport of electronic signals. In one known arrangement, the backplane connectors consist of a plastic housing and metal-plated (e.g., gold-plated) pins, often referred to as contacts. The circuit boards include a connector tab on one edge with metallic conductive elements (e.g., gold-plated “fingers”) that mate electrically with the corresponding metal contacts of the backplane connector when inserted.

Equipment shelves are not always fully populated with circuit boards. For example, full capacity may not be used at all times or at least initially upon system installation. As such, some circuit board positions may remain unequipped, i.e., open, until more capacity is demanded and a new board is inserted. However, unequipped positions in an equipment shelf can be problematic. For example, circuit boards or portions of circuitry on circuit boards that are in positions adjacent to the unequipped position are vulnerable to environmental effects (e.g., temperature variations, dust particles, etc.) as well as inadvertent tampering or intrusion. Unequipped positions can also disrupt airflow in a convection-cooled shelf by diverting cooled air from operational circuit boards.

Unequipped positions in an equipment shelf can also degrade operational performance. For example, some communication systems include protection features to maintain communications in the event of equipment failures, e.g., when a faulty circuit board must be removed. More specifically, one circuit board slot in an equipment shelf may be designated as a “protection” slot for carrying the signal transmission in the event of the removal of a failed circuit board from one of the “service” slots. To facilitate a switchover in signal transmission from service to protection, a protection bus is included on the backplane for connecting the signals. For example, the protection bus carries a signal transmission to and from any one of the service slots to the protection slot. Normally, when a circuit board is removed from a service slot, the signal transmission carried by that failed circuit board is routed via the protection bus to the protection slot. Such routing is accomplished via wiring from shorting contacts in the backplane connector corresponding to the circuit board that is removed.

For example, FIG. 1 shows a portion of a connector 110, which would be part of a backplane in an equipment shelf, and a portion of a circuit board 101 that would mate with connector 110. As shown, connector portion 110 includes contacts 111 and a pair of shorting contacts 112 and 114, which are spring action type contacts. When circuit board 101 is not inserted into connector 110, shorting contacts 112 and 114 are normally closed, thereby remaining in contact with each other and creating an electrical connection between them, i.e., a short circuit connection such that a signal supplied to one side of the shorting contacts flows directly to the opposing side. Upon insertion of circuit board 101, contacts 102 on circuit board 101 engage with contacts 111 as well as the pair of shorting contacts 112 and 114. In this manner, shorting contacts 112 and 114 are separated.

Continuing with the above protection switching example, the shorting contacts in a backplane connector provide the electrical connection to the protection bus when the shorting contacts are closed, i.e., when a circuit board has been removed. Stated otherwise, when a circuit board is inserted and the shorting contacts are open, e.g., during normal operation when signals are processed through the working circuit board, the service slot is isolated from the protection bus. When the failed circuit board is removed, the shorting contacts close and provide the electrical connection from the circuit board slot to the protection bus so that transmission can be routed to the protection slot.

While protection switching is a desirable feature for handling equipment failures, a problem arises when a circuit board slot is intentionally left unequipped, such as when full capacity of the equipment shelf is not used, and a switchover to the protection bus is both unnecessary and undesirable. Because the shorting contacts in the unequipped position remain closed, the wiring/cabling corresponding to the unequipped slot essentially becomes a stub that is connected to the wiring path of the protection bus that is carrying actual customer traffic. As with any unterminated transmission line, the signal will propagate down the stub in this unequipped slot, be reflected, and add to and/or subtract from the desired signal, thus interfering with the ability of the receiver to properly discern the signal.

Several circuit board “blanks” are known which have been used to fill unequipped positions in an equipment shelf. For example, circuit blanks have been developed for use in equipment shelves to equalize airflow backpressure. However, these circuit blanks are not suitably designed to engage the backplane connectors and therefore do not address the aforementioned problem associated with the operation of the shorting contacts in the backplane connectors. Another type of circuit blank shown in FIG. 2 (blank 200) comprises a printed circuit board (PCB) 201 with a fiberglass construction and a connector tab 202 that includes a plurality of gold-plated conductive fingers 205. Blank 200 also includes levers 210 and 212 that are rotatable about pivot point 211 to insert and remove blank 200 from an equipment shelf and that also function as a faceplate, in a well-known manner. As such, blank 200 is constructed like an operational circuit pack, e.g., similar PCB construction except without any signal processing circuitry thereon, gold-plated fingers for mating with a backplane connector, and the rotatable lever assembly to provide the necessary insertion force to insert the blank into a dual density edge connector on the backplane.

However, these similarities also result in some significant disadvantages. Because of the density of the contact field (e.g., number of contacts) in the dual density edge connectors, thickness of the printed circuit boards, and the metal-to-metal mating of contacts, a considerable amount of insertion force is required for inserting blank 200 into a backplane. The amount of required insertion force, as well as the potential misalignments between the metallic contacts on the blank and those in the backplane connection during insertion, results in increased stress and failure of these circuit blanks and/or backplane connectors over the course of repeated insertions. Additionally, blank 200 is relatively expensive and traditionally has long lead times to manufacture. Furthermore, because the applied insertion force must follow the lever assembly as it rotates, usually one circuit blank is inserted at a time.

### SUMMARY OF THE INVENTION

In an equipment shelf that utilizes backplane connectors having metallic contacts, a circuit card blank that separates the contacts, requires a minimal amount of insertion force, and substantially reduces wear and tear on the backplane connectors is realized according to the principles of the invention using an integrally molded design that includes a non-metallic connector tab adapted for insertion into a backplane connector such that the connector tab serves as an insulating layer thereby preventing electrical connection between the contacts. Because the circuit card blank is integrally molded without metallic contacts on the connector tab, fabrication cost, complexity and lead time are significantly less than with prior circuit blanks. Moreover, multiple circuit card blanks can be inserted into the equipment shelf simultaneously because of the reduced amount of required insertion force.

According to one illustrative embodiment of the invention, a circuit card blank includes a base for positioning the blank in an unequipped position of an equipment shelf and a non-metallic connector tab integrally molded with and located at an edge of the base. The connector tab is adapted for insertion into a backplane connector having metallic contacts, including shorting contacts, such that the connector tab serves as an insulating layer thereby preventing electrical connection between the shorting contacts. A snap-fit clip can also be integrally molded with the base for retaining the circuit card blank in the equipment shelf and preventing self-extraction.

### BRIEF DESCRIPTION OF THE DRAWINGS

A more complete understanding of the principles of the invention may be obtained from consideration of the following detailed description in conjunction with the drawing, with like elements referenced with like references, in which:

FIG. 1 shows a perspective view of a portion of a circuit board and a backplane connector with shorting contacts known in the prior art;

FIG. 2 shows a side elevation view of a prior art circuit blank;

FIG. 3 shows a side elevation view of one illustrative embodiment of a circuit card blank according to the principles of the invention;

FIG. 4 shows a perspective view of the circuit card blank from FIG. 3 inserted into an equipment shelf according to the principles of the invention;

FIG. 5 is a top plan view of the circuit card blank from FIG. 3; and

FIG. 6 is a front elevation view of the circuit card blank from FIG. 3.

### DETAILED DESCRIPTION

It should be noted that the terms “circuit board”, “circuit card”, and “circuit pack” may be used interchangeably throughout the description and are not being used in any limiting manner with regard to the description of the various embodiments. In particular, the present invention would be applicable to various implementations, whether on a board, pack or card type of apparatus, which are used in conjunction with some type of equipment housing such as an equipment shelf, bay, compartment, and so on.

It should also be noted that while the embodiments described herein are particularly well-suited for equipment shelves that utilize backplane connectors of the type having shorting contacts for protection switching functionality, it will be apparent to those skilled in the art that the circuit blank according to the principles of the invention can also be used with an equipment shelf or housing that has contacts that may operate similarly (e.g., open and closed positions), but which provide different functionality other than protection switching. Moreover, a circuit blank according to the principles of the invention can also be used in equipment shelves having different types of backplane connectors including, for example, dual density edge connectors, single density edge connectors, connectors with or without shorting contacts, and so on. As such, the types of equipment shelves and backplane connectors that are described herein for use with the various embodiments of the present invention are meant to be illustrative only and not limiting in any manner.

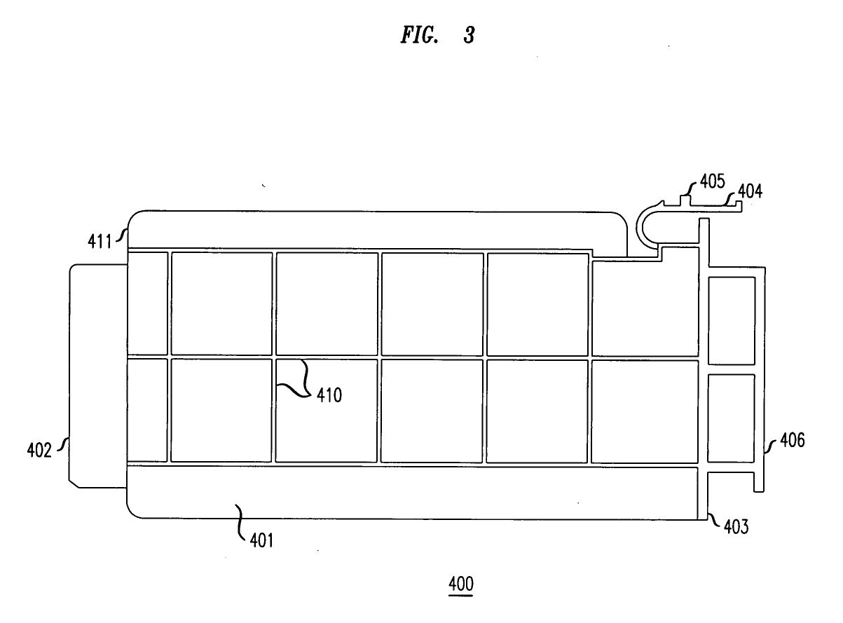

FIG. 3 shows one illustrative embodiment of the invention. As shown, circuit card blank 400 includes a base (which can also be referred to as a circuit board portion) 401 and an integrally molded connector tab 402 located at an edge 411 of base 401. Circuit card blank 400 further includes a faceplate 403 at an opposite edge from edge 411 of base 401 (as shown in FIGS. 3 and 6). As will be apparent to one skilled in the art, faceplate 403 may be attached to base 401 in a variety of ways. In the embodiment illustrated in FIGS. 3 and 6, faceplate 403 is integrally molded and perpendicularly attached to base 401.

Blank 400 also includes handle mechanism 406, as shown in FIGS. 3, 5 and 6, which is integrally molded with base 401 and faceplate 403. Handle mechanism 406 is capable of inserting and removing circuit card blank 400 from an equipment shelf as will be described in further detail below.

As shown in FIGS. 3 and 6, blank 400 also includes a deformable, snap-fit clip 404 with locking tab 405 for retaining blank 400 in the equipment shelf when inserted. The specific operation of snap-fit clip 404 will be described below in more detail.

As will be apparent to one skilled in the art, blank 400 may be effectively constructed in a variety of ways, provided that blank 400 can be inserted in an equipment shelf in a manner equivalent to the insertion of operational circuit boards in equipped positions. For example, base 401 may simply be formed as a uniform member with rectangular dimensions equivalent to those of the circuit boards. As depicted in FIG. 3, base 401 may also include optional rib members 410 that extend horizontally and vertically along base 401 to provide increased rigidity and to conserve material. Alternatively, it is also contemplated that material can even be selectively removed between rib members 410 to further conserve additional material.

It will also be apparent to those skilled in the art that circuit blank 400 can be constructed from a variety of materials. For example, an injection molding process may be used to form circuit blank 400 from a variety of commercially available plastic resins. Acrylonitrile-Butadine-Styrene (ABS) is one example of an amorphous polymer resin that provides reasonable strength at a low cost. Alternatively, materials such as polycarbonate (PC) may provide improved impact strength at higher cost. Various blends of ABS and PC may also be used to obtain a desired balance between strength, cost and ease of manufacture. Polyetherimide is yet another material that is suitable for circuit blank 400. Other currently known and commercially available materials, as well as materials yet-to-be developed, which are suitable for use in a circuit blank according to the principles of the invention, will be readily apparent to those skilled in the art in view of the teachings herein as well as routine design considerations. As such, the teachings herein are only meant to be illustrative and not limiting in any manner.

Other design considerations will also be apparent to those skilled in the art when selecting an appropriate material for constructing the molded circuit blank according to the principles of the invention. For example, existing or to-be-developed safety and performance standards may dictate certain compliance requirements, such as flame retardation. Presently, some applicable standards might include Underwriters Laboratories Standard 94 V-O and Telcordia GR-63-CORE by way of example.

In contrast to prior arrangements that use a printed circuit board (PCB) construction, such as a rough-machined fiberglass (FR-4) type of surface with gold-plated fingers, the molded plastic construction of circuit blank 400 results in less wear and tear on backplane connectors because of the elimination of the metallic contacts on the circuit blank. In particular, there is no metal-to-metal mating of contacts between the blank and the backplane connector as with the prior art circuit blanks. Another common problem that contributes to wear and tear in the prior arrangements is damage to the metallic contacts (both on the prior art circuit blanks and to the backplane connector) caused by misalignments during insertion of the circuit blank. That is, the metallic gold-plated fingers of the prior art circuit blanks are supposed to mate with corresponding metal contacts within the backplane connector when the board is inserted. However, misalignment can sometimes occurs when the prior art circuit blank is inserted into a backplane connector. These misalignments can remove some of the metallic coating and therefore damage both backplane connectors and circuit cards, especially with repeated insertions and removals of circuit cards. By contrast, the molded plastic construction of the circuit blank according to the principles of the invention eliminates this problem altogether. Additionally, the electrical connection resulting from the mating of metallic contacts on prior art circuit blanks with the metallic contacts of a backplane connector can result in other problems including, for example, arcing between the ground contact and power contact on a circuit blank and/or backplane connector. The molded plastic construction of the circuit blank according to the principles of the invention eliminates this problem as well.

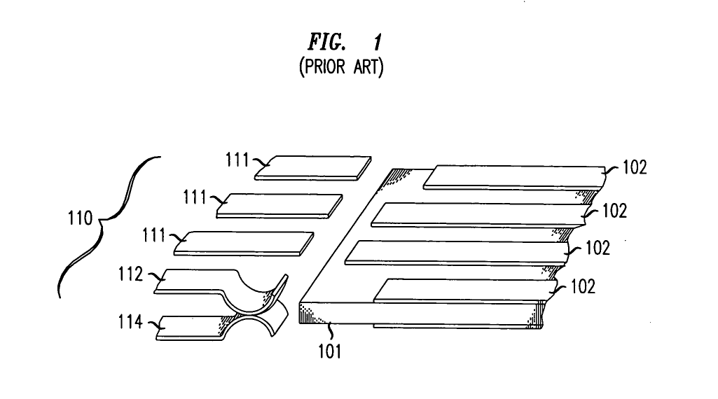

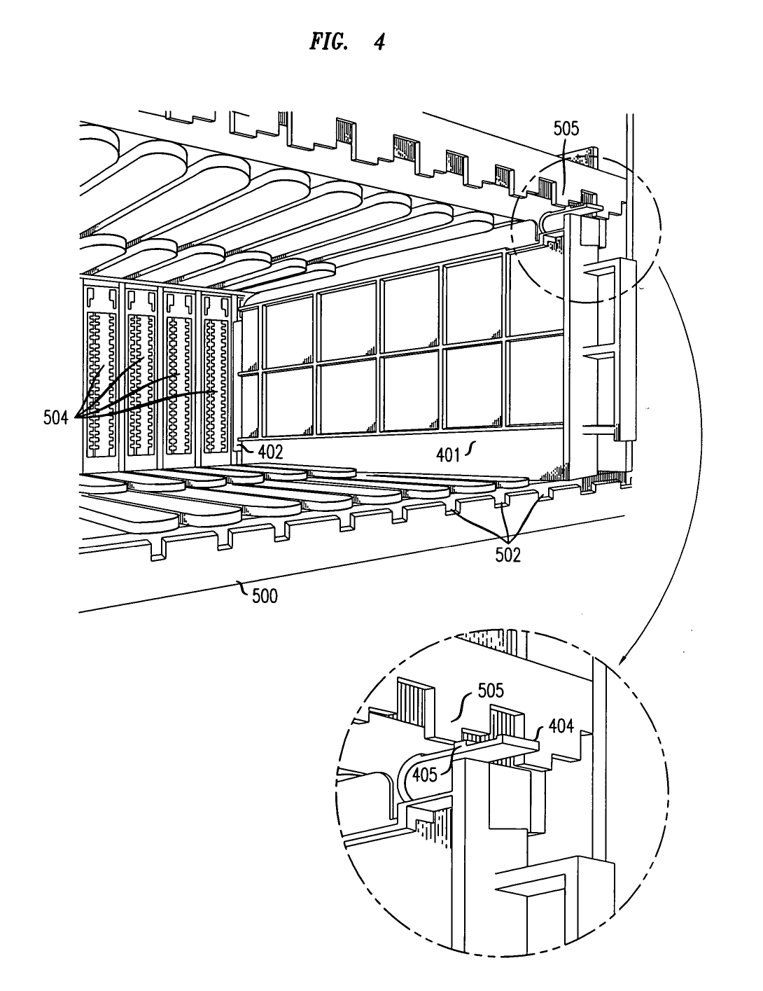

FIG. 4 illustrates the manner in which a circuit blank according to the principles of the invention can be inserted into an equipment shelf. More specifically, FIG. 4 shows a simplified diagram of equipment shelf 500 that includes a plurality of circuit card slots, defined in FIG. 4 by lower slots 502 and upper slots 505. Shelf 500 further includes backplane connectors 504, shown in FIG. 4 as dual-density edge connectors, which are well known to those skilled in the art. In operation, circuit cards are inserted into shelf 500 using slots 502 and 505 so that the cards engage and mate with connectors 504 on the backplane of the equipment shelf. According to the principles of the invention, base 401 of circuit blank 400 can be similarly inserted into shelf 500 via slots 502 and 505 such that connector tab 402 is inserted into backplane connector 504. Although not explicitly shown in FIG. 4, backplane connector 504 includes shorting contacts such as contacts 112 and 114 as previously described and shown in FIG. 1. As such, when connector tab 402 is inserted into backplane connector 504 in shelf 500, the shorting contacts (not shown) would be separated by connector tab 402. Because of the molded plastic construction of blank 400, connector tab 402 effectively serves as an insulating layer between the metallic shorting contacts to prevent the electrical connection between the shorting contacts. In this manner, the aforementioned problems associated with leaving a slot unequipped are overcome by using blank 400 according to the principles of the invention.

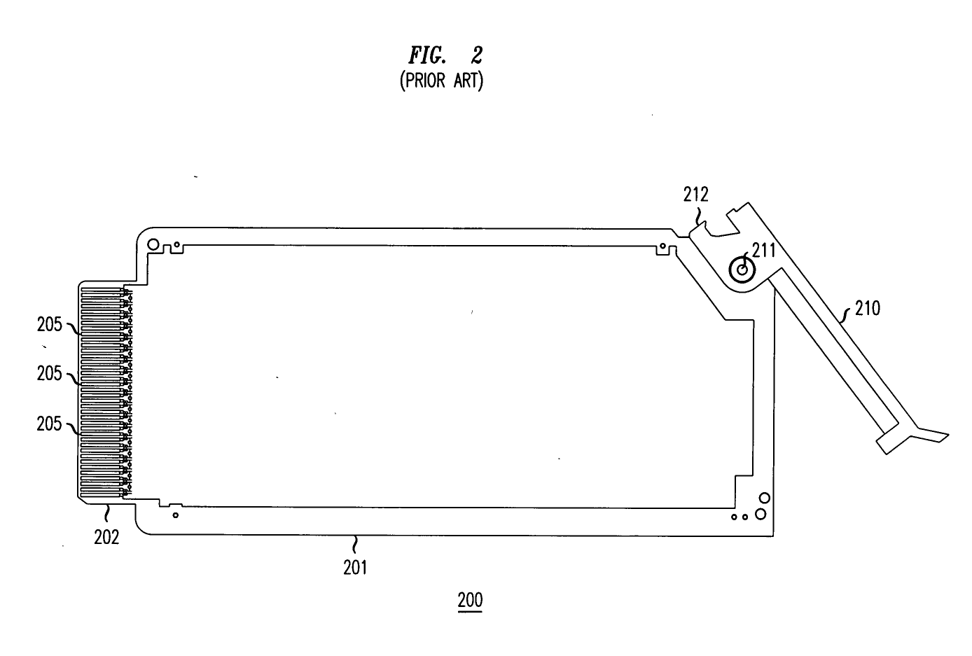

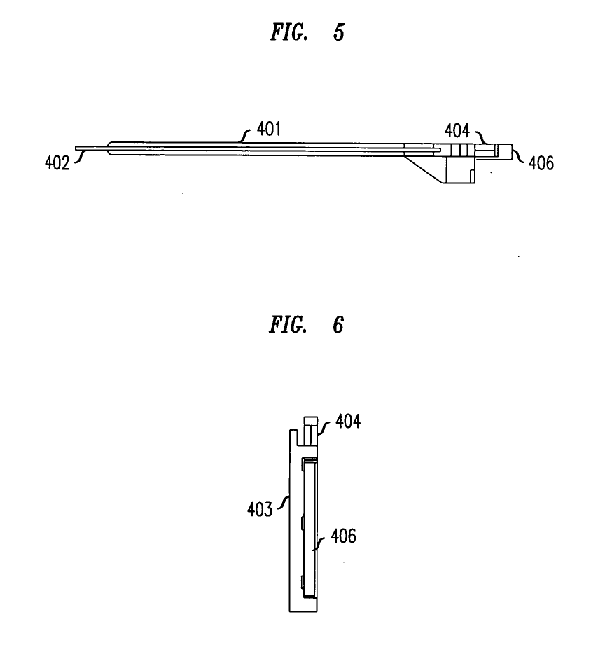

According to another aspect of the invention, circuit blank 400 requires less insertion force than conventional circuit blanks and also substantially reduces wear and tear on both the circuit blank itself as well as the backplane connectors in an equipment shelf. In the illustrative embodiment shown in FIG. 5, for example, circuit blank 400 is constructed so that the thickness of connector tab 402, which is inserted into a backplane connector, is less than the thickness of base 401. As such, less material is inserted between shorting contacts in the high density backplane connectors thus making it easier to insert connector tab 402 with backplane connector 504 (FIG. 5). The reduced thickness is also possible because of the molded plastic construction of circuit blank 400. In this manner, less force is exerted on the contacts within the backplane connector, thereby reducing the wear and tear on the connectors. By way of example, analysis has shown that a 40% reduction in insertion force can be realized using a circuit blank according to the principles of the invention. A circuit blank according to one illustrative embodiment of the invention exerted a maximum insertion force of 202.5 grams per shorting contact, while a conventional board such as that shown in FIG. 2 exerted a maximum insertion force of 332 grams per shorting contact.

The variable thickness of circuit blank 400, as shown in FIG. 5, is meant to be illustrative only. In particular, other design and operational requirements will be apparent to those skilled in the art when choosing the appropriate construction parameters, e.g., thickness of the various elements of circuit blank 400. For example, desired rigidity of the blank, the density and spacing of contacts within the backplane connector, and other manufacturing considerations are all factors that can help determine the appropriate dimensions of the various components on circuit blank 400 by those skilled in the art.

Because of the reduced amount of insertion force needed to insert circuit blank 400 into an equipment shelf as compared with prior arrangements, the mechanism for inserting circuit blank 400 into an equipment shelf is also greatly simplified over the prior arrangements and in a manner that reduces the stress on the circuit blank itself.

As previously described, the prior arrangements that use lever assemblies, such as that shown in FIG. 2, add mechanical stress to the circuit blank itself because of the nature of the lever operation and the forces imparted on the board as it is being inserted into a backplane connector. In particular, lever 210 shown in FIG. 2 operates, in a well-known manner, by imparting a force that is both downward and forward as the board is being inserted into an equipment shelf. As such, stress is applied to the bottom edge of the board that is in contact with the lower slot of the equipment shelf and stress is also applied to the portion of the blank where pivot point 211 is located.

By contrast, circuit pack blank 400 can be inserted into an equipment shelf (such as shelf 500 in FIG. 4) by simply pushing on handle mechanism 406 in a direction toward the backplane of the equipment shelf. As previously described, the ease of insertion results from the reduced thickness of material that can be realized using a molded plastic construction. Accordingly, the features of circuit blank 400 result in less mechanical stress and resultant wear and tear on both the circuit blank itself as well as the backplane connectors even with repeated insertions/removals.

Additionally, because of the reduced insertion force as well as the construction of handle mechanism 406, a technician can simultaneously install multiple circuit blanks in an equipment shelf much more easily and rapidly in contrast to the prior arrangements that use lever assemblies in which usually a single board is inserted at a time because of the nature of the lever operation and the amount of required insertion force.

According to another aspect of the invention, circuit pack blank 400 engages and is secured in an equipment shelf using snap-fit clip 404 with locking tab 405, which can also be integrally molded with faceplate 403 and/or base 401 as shown in FIG. 3. In one illustrative embodiment, snap-fit clip 404 is deformable to facilitate the insertion and then locking or retention of the circuit pack blank in the equipment shelf. The cutaway view in FIG. 4 illustrates these features of the invention in more detail. In operation, a downward force is applied to snap-fit clip 404 in a direction toward base 401, which is elastically deformable, so that the blank can be inserted into the slot in equipment shelf 500 and so that locking tab 405 can pass under the top edge 505 (e.g., notches) of equipment shelf 500. Once fully inserted, the deformable snap-fit clip 404 springs upward and the locking tab 405 is positioned behind the top edge of equipment shelf 500. In this manner, circuit pack blank 400 is retained in the equipment shelf and will not self-extract (e.g., from vibration, etc) or otherwise disengage from the equipment shelf. To remove circuit pack blank 400 from equipment shelf 500, downward force is again applied to snap-fit clip 404 so that the locking tab 405 can clear under the top edge of equipment shelf 500. Upon removal of circuit pack blank 400, snap-fit clip 404 deforms to its original shape, i.e., uncompressed position.

The integrally molded snap-fit clip 404 is also less costly and easier to manufacture than prior latch/lever assemblies and, because there are less moving parts and no need for a substantial rotational moment couple, mechanical stresses on the circuit pack blank and equipment shelf are substantially reduced as compared to the aforementioned arrangements that use conventional latch/lever assemblies. In another illustrative embodiment, snap-fit clip 404 can also be a separate part that is fastened or otherwise attached to base 401 and/or faceplate 403, e.g., by rivets, screws, heat posted, and so on. Other means for fabricating and attaching snap-fit clip 404 to circuit pack blank 400 will be apparent to those skilled in the art.

According to another aspect of the invention, circuit pack blank 400 also prevents inadvertent access or intrusion into the otherwise unequipped slot and distributes airflow more uniformly within the equipment shelf. Moreover, the plastic construction results in improved electro-static discharge (ESD) performance as compared to prior circuit blanks.

The foregoing is merely illustrative of a few exemplary embodiments according to the principles of the invention. Those skilled in the art will be able to devise numerous arrangements, which, although not explicitly shown or described herein, nevertheless embody those principles that are within the spirit and scope of the invention. Such modifications are therefore contemplated by the teachings herein. Accordingly, the scope of the invention is only limited by the claims appended hereto.

1. A circuit pack blank for use in an unequipped position in an equipment shelf, the blank comprising:
a base for positioning the blank in the unequipped position, the base including an integrally molded, non-metallic connector tab located at an edge of the base, wherein the connector tab is adapted for insertion into a backplane connector having metallic contacts, such that the connector tab serves as an insulating layer thereby preventing electrical connection between the contacts.

2. The circuit pack blank according to claim 1, wherein the metallic contacts include at least one pair of shorting contacts and wherein the connector tab prevents electrical connection between the shorting contacts.

3. The circuit pack blank according to claim 1, wherein the base and connector tab comprise an integrally molded plastic construction.

4. The circuit pack blank according to claim 3, wherein the plastic includes one or more materials selected from the group consisting of polycarbonate (PC), acrylonitrile-butadiene-styrene (ABS), and polyetherimide.

5. The circuit pack blank according to claim 1, wherein the thickness of the connector tab is less than the thickness of the base.

6. The circuit pack blank according to claim 1, wherein the base comprises ribbed members extending in at least one direction along the base.

7. The circuit pack blank according to claim 1, further comprising a means for retaining the circuit pack blank in the unequipped position of the equipment shelf.

8. The circuit pack blank according to claim 7, wherein the means for retaining comprises a snap-fit clip integrally molded with the base.

9. The circuit pack blank according to claim 1, further comprising a faceplate that includes a substantially planar member perpendicularly attached at a second edge of the base that is opposite the edge where the connector tab is located, the faceplate further including a means for inserting and removing the circuit pack blank from the equipment shelf.

10. The circuit pack blank according to claim 9, wherein the means for inserting and removing is a handle integrally molded with the faceplate and the base.

11. A circuit pack blank for use in an unequipped position in an equipment shelf, the equipment shelf including a backplane having connectors with metallic shorting contacts, the blank comprising:
a circuit board including an integrally molded edge adapted for insertion into a connector in the backplane, the circuit board comprising an insulating material so that the edge of the circuit board prevents electrical connection with and between the shorting contacts when inserted into the backplane connector.

12. The circuit pack blank according to claim 11, wherein the circuit board comprises an integrally molded plastic construction.

13. The circuit pack blank according to claim 11, wherein the thickness of the circuit board is non-uniform such that the thickness at the edge adapted for insertion into the backplane connector is less than the thickness of other sections of the circuit board, thereby reducing the amount of insertion force needed to insert the circuit board into the backplane connector.

14. The circuit pack blank according to claim 11, further comprising a means for retaining the circuit pack blank in the unequipped position of the equipment shelf.

15. The circuit pack blank according to claim 14, wherein the means for retaining is a snap-fit clip integrally molded with the circuit board.

16. A circuit card blank for use in an unequipped position in an equipment compartment that includes a connector having metallic contacts, the blank comprising:
a base for positioning the blank in the unequipped position, the base including an integrally molded, non-metallic connector tab located at an edge of the base, wherein the connector tab is adapted for insertion into the connector, such that the connector tab serves as an insulating layer thereby preventing electrical connection between at least one pair of the metallic contacts.

17. An equipment shelf for housing electronic apparatus, the shelf comprising:
a plurality of circuit card slots, each adapted to receive a circuit card;
a backplane including one or more connectors corresponding to each of the plurality of circuit card slots, wherein at least one connector includes shorting contacts; and
a circuit card blank including an integrally molded connector tab at an edge of the circuit card blank, wherein the connector tab is inserted into one of the connectors thereby preventing electrical connection with and between the shorting contacts.
